(19) United States
(12) Patent Application Publication
(10) Pub. No.: US 2010/0212717 A1
(43) Pub. Date: Aug. 26, 2010

(54) Solar collector with optical waveguide

(76) Inventors: John P. Whitlock, Lebanon, OR (US); Scott Lerner, Portland, OR (US); David G. Leigh, Corvallis, OR (US); Stephan R. Clark, Albany, OR (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/378,827

(22) Filed: Feb. 20, 2009

(51) Int. Cl. H01L 31/052; B23P 15/26

(52) U.S. Cl. 136/246; 29/890.033

(57) ABSTRACT

A solar energy collection system includes a first photovoltaic cell sensitive to radiation in a first wavelength range, a second photovoltaic cell sensitive to radiation in a second wavelength range, and a first waveguide configured to direct radiation toward the first and second photovoltaic cells and defining a longitudinal axis substantially non-perpendicular to a radiation receiving surface of at least one of the photovoltaic cells.

### BACKGROUND

The field of photovoltaics generally relates to multi-layer materials that convert sunlight directly into DC electrical power. The basic mechanism for this conversion is the photovoltaic (or photoelectric) effect. Photovoltaic (PV) devices are popularly known as solar cells or PV cells.

Solar cells are typically configured as a cooperating sandwich of p-type and n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer, creating a small electrical imbalance inside the solar cell. This results in an electric field in the vicinity of the junction.

When an incident photon excites an electron in the cell into the conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the n-type side, and the hole moving toward the p-type side of the junction. This creates an overall charge imbalance in the cell, so that if an external conductive path is provided between the two sides of the cell, electrons will move from the n-type side back to the p-type side along the external path, creating an electric current. In practice, electrons may be collected from at or near the surface of the n-type side by a conducting grid that covers a portion of the surface, while still allowing sufficient access into the cell by incident photons.

Such a photovoltaic structure, when appropriately located electrical contacts are included and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. The resulting voltage can also be used to charge batteries and energize low voltage circuitry.

One type of solar cell is a crystalline silicon PV cell, in which two layers of silicon that have been doped with different types of atoms form the p-type and n-type semiconductor layers. Silicon-based PV cells can reach efficiencies of around 20%, but can be relatively fragile and difficult to transport and install. Another type of solar cell that has been developed for commercial use is a “thin-film” PV cell, in which several thin layers of inorganic material are deposited sequentially on a substrate to form a working cell. This is typically accomplished through evaporation (such as vacuum deposition) or sputtering. In comparison to crystalline silicon PV cells, thin-film PV cells require less light-absorbing material to create a working cell, and thus can reduce processing costs. Furthermore, inorganic thin-film cells have exhibited efficiencies approaching 20%, which rivals or exceeds the efficiencies of most crystalline cells. A third type of solar cell is a thin-film cell based on organic polymers of various types. These cells are relatively lightweight, inexpensive and flexible.

Thin-film PV materials may be deposited either on rigid glass substrates, or on flexible substrates. Glass substrates are relatively inexpensive, but suffer from various shortcomings, such as a need for substantial floor space for processing equipment and material storage, specialized heavy duty handling equipment, a high potential for substrate fracture, increased shipping costs due to the weight and fragility of the glass, and difficulties in installation. In contrast, roll-to-roll processing of thin flexible substrates allows for the use of compact, less expensive vacuum systems, and of non-specialized equipment that already has been developed for other thin-film industries. PV cells based on thin flexible substrate materials also require comparatively low shipping costs, and exhibit a greater ease of installation than cells based on rigid substrates. On the other hand, thin-film substrates, such as thin sheets of stainless steel, are typically more expensive than glass substrates.

### BRIEF DESCRIPTION OF THE DRAWINGS

FIG. 1 is a side elevational view of a solar radiation collection system illustrating multiple embodiments of the present disclosure.

FIG. 2 is a side elevational view of another solar radiation collection system, illustrating multiple embodiments of the present disclosure.

FIG. 3 is a side elevational view of a solar radiation collection system, according to an embodiment of the present disclosure.

FIG. 4 is a side elevational view of a solar radiation collection system, according to another embodiment of the present disclosure.

FIG. 5 is a side elevational view of a solar radiation collection system, according to yet another embodiment of the present disclosure.

FIG. 6 is a side elevational view of a solar radiation collection system, according to still another embodiment of the present disclosure.

FIG. 7 is a side elevational view of a solar radiation collection system, according to still another embodiment of the present disclosure.

FIG. 8 is a side elevational view of a solar radiation collection system, according to still another embodiment of the present disclosure.

FIG. 9 is a side elevational view of a solar radiation collection system, according to still another embodiment of the present disclosure.

FIG. 10 is a side elevational view of a solar radiation collection system, according to still another embodiment of the present disclosure.

FIG. 11 is a side elevational view of a solar radiation collection system, according to still another embodiment of the present disclosure.

FIG. 12 is a flow diagram illustrating a method of manufacturing a solar energy collection system.

FIG. 13 if a flow diagram illustrating a method of collecting radiation.

### DETAILED DESCRIPTION

Regardless of which type of PV cell is used, the photovoltaic materials of a particular cell are typically effective in a particular range of solar radiation wavelengths. If the photon energy is less than the band gap energy, which is the difference between the valence and conduction bands, no electron hole pairs are generated. For any photon energy greater than the band gap, the electron will be excited to the highest energy and then will move to the lowest energy state which is at the bottom of the valence band, before being used by an external circuit. Any energy greater than the band gap will be lost as heat. An effective wavelength range for crystalline silicon-based PV cells may be from 300-600 nanometers (nm), whereas some inorganic thin-film PV cells may be most effective in the wavelength range from 600-1200 nm. Other PV cells, such as thin-film cells based on organic materials, may be particularly effective for ultraviolet radiation in the wavelength range from 100-400 nm. Because different types of PV cells are responsive to different ranges of solar radiation, using just one particular type of cell in a given solar device does not generally make optimal use of the full range of incident solar wavelengths.

Photovoltaic systems are also typically limited by the requirement that PV cells must be positioned so as to receive direct solar radiation, i.e. the cells must be positioned within the line of sight of the sun. Regardless of the efficiency of the cells, this limits the amount of solar radiation that can be converted into electricity per unit area of PV material, and thus results in a relatively high minimum expense per watt of electricity output. Optical concentrators such as converging lenses and mirrors have been used to concentrate solar radiation onto a PV cell, but such systems are still limited because the PV cell must be positioned directly in the path of the concentrated radiation. The present solar radiation collection system provides for receipt and direction of a relatively large amount of solar radiation toward one or more PV cells.

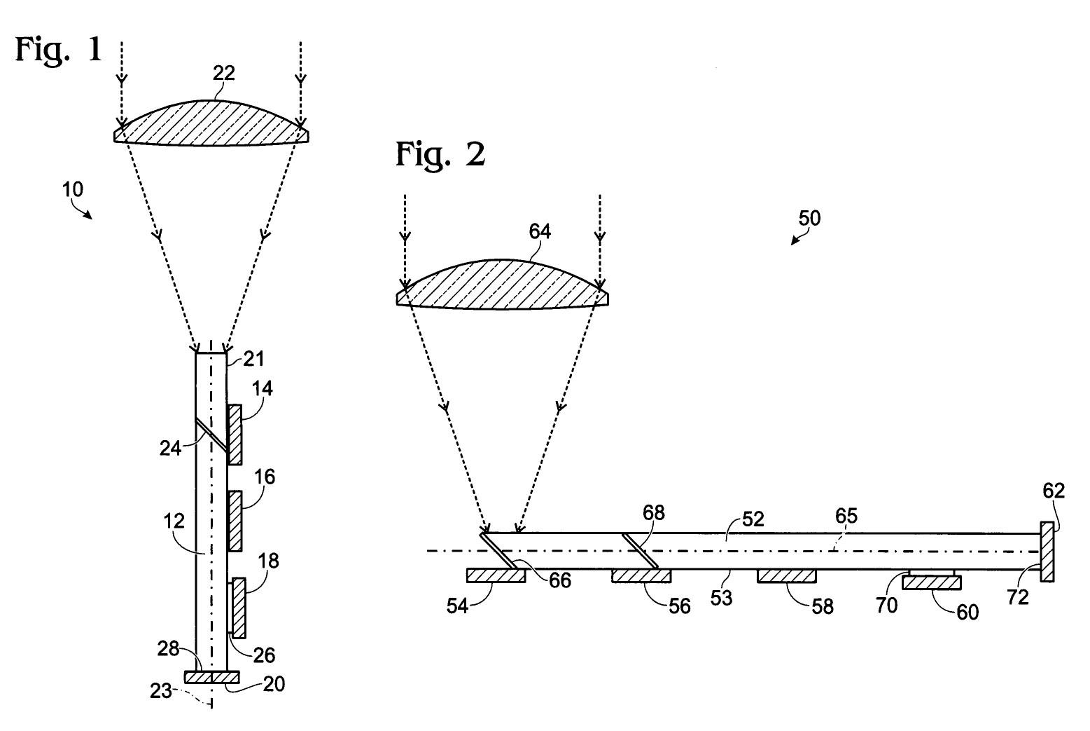

FIG. 1 is a side elevational view of a solar energy collection system, generally indicated at 10, according to multiple embodiments of the present teachings. System 10 includes a waveguide 12 configured to receive and direct incident solar radiation, and a plurality of PV cells 14, 16, 18 and 20 configured to receive radiation directed by the waveguide. As described in more detail below, each PV cell may be sensitive to radiation within a particular wavelength range, in the sense that each cell may most efficiently convert radiation within a particular energy range into electricity. As depicted in FIG. 1, system 10 also may include an optical concentrating element, in the form of a converging lens 22, which is configured to concentrate and direct solar radiation toward waveguide 12. Waveguide 12 may be a solid piece of material having a known index of refraction and which is transparent to at least a substantial fraction of the solar radiation spectrum. Alternatively, waveguide 12 may include two or more nested layers of material, with each surrounding layer of material having a lower index of refraction than the material it surrounds. Furthermore, waveguide 12 may include multiple sections of waveguide material disposed in contact with each other, so that the multiple sections effectively function as a single waveguide.

Regardless of the precise construction of the waveguide and whether or not the incident radiation is directed by an optical concentrating element, the waveguide defines a longitudinal axis, and radiation incident on the waveguide continues or is directed by the waveguide in a direction generally along its longitudinal axis and toward the PV cells. If a particular ray of radiation encounters one of the lateral boundaries of the waveguide, such as boundary 21 (or a boundary between layers of material within the waveguide), at an angle less than a particular critical angle relative to the boundary, the ray will be internally reflected within the waveguide according to well known principles of optics. The critical angle is given by

$${θ}_{c} = arc sin ( \frac{{n}_{2}}{{n}_{1}} ) ,$$

where n₂ is the index of refraction of the less dense surrounding medium and n₁ is the index of refraction of more dense medium in which the ray is traveling when it encounters the boundary. In this manner, it is well known in the art that radiation such as solar radiation can travel within a waveguide with only minimal losses of energy.

Radiation traveling within waveguide 12 may be directed toward and received by one or more of PV cells 14, 16, 18 and 20 in a variety of ways. First, some or all of the radiation may be directed toward cell 14 by a reflective or at least partially reflective optical component 24 disposed within the waveguide. Optical component 24 may, for example, take the form of a dichroic element that reflects a first portion of the radiation it receives toward cell 14 and transmits a second portion of the radiation it receives, so that the transmitted radiation continues along the longitudinal direction defined by the waveguide and toward cells 16, 18 and 20. Alternatively, optical component 24 may take the form of a mirror or other similarly reflective surface, in which case substantially all of the radiation that encounters the reflective optical component will be directed toward cell 14.

PV cells 14, 16 and 18 each defines a radiation receiving surface oriented substantially parallel to the longitudinal axis 23 of waveguide 12. It should be appreciated, however, that the present teachings contemplate that one or more of cells 14, 16 and 18 may be disposed along a lateral side boundary such as boundary 21 of the waveguide but oriented at a non-zero angle to longitudinal axis 23, where the longitudinal axis remains substantially non-perpendicular to the radiation receiving surface. Also as shown in FIG. 1, some or all of the PV cells may be disposed in direct physical contact with the waveguide. However, one or more of the cells may be disposed along a lateral side of the waveguide but not directly adjacent to or in physical contact with the waveguide. In addition, as described below, one or more cells may be disposed with its radiation receiving surface oriented substantially perpendicular to the longitudinal axis of the waveguide, for instance if the waveguide is positioned at or near a distal end portion of the waveguide.

Some of the radiation within waveguide 12 may be transmitted directly through a lateral side portion of the waveguide and toward one or more of the PV cells, such as to PV cell 16 as depicted in FIG. 1. As described previously, transmission of radiation from within the waveguide through lateral side boundary 21 of the waveguide will occur for radiation that arrives at the lateral outer boundary of the waveguide at an angle that exceeds the critical angle for internal reflection. This type of transmission may be arranged, for example, by suitably orienting the waveguide with respect to the incident solar radiation, and/or by shaping a side portion of the waveguide to affect the angle of incidence in an appropriate manner. Furthermore, selective transmission through the side of the waveguide may be accomplished through the use of suitable dielectric coatings, either alone or in conjunction with proper orientation of incident illumination and/or boundary shape alteration, to make the light angles greater than the critical angle. Applying dielectric coatings can select the wavelengths of light that may be transmitted through the side of the waveguide while allowing the other wavelengths to continue traveling within the waveguide. The index of refraction varies slowly as a function of wavelength, and in general several dielectric layers are needed to create a desired transmission versus wavelength profile.

As a third method for directing radiation from the waveguide toward one of the PV cells, a dichroic material such as a dichroic prism 26 may be disposed at the interface between a lateral side portion, such as boundary 21 of waveguide 12 and a particular cell, such as cell 18 depicted in FIG. 1. This dichroic prism material may be configured to facilitate transmission of radiation within a particular range of wavelengths through the side of the waveguide and to PV cell 18, while reflecting the remaining incident radiation. The radiation reflected back into the waveguide will again continue traveling within the waveguide, generally along the longitudinal axis of the waveguide and toward PV cell 20 in the embodiment of FIG. 1.

Finally, radiation may be directed toward PV cell 20 simply by placing cell 20 at a distal end 28 of the waveguide as depicted in FIG. 1. Radiation incident on distal boundary 28 of the waveguide is more likely to be transmitted through the distal boundary of the waveguide than light incident on the other boundaries, because the angle of incidence is more likely to exceed the critical angle for internal reflection. Note that in general, light that enters an extruded square cross-section waveguide will satisfy the internal reflection criteria at the walls and satisfy the transmission criteria at the distal boundary. Thus, cell 20 may be used to collect any radiation remnants that were not previously directed toward cells 14, 16 and 18, or the system may be configured to direct only radiation within a particular wavelength range toward cell 20, for example through a suitable choice of dichroic materials disposed within the waveguide.

Some or all of PV cells 14, 16, 18 and 20 may be selected to have properties that match the type of radiation directed toward each particular cell by system 10. In other words, the cells may be more effective at collecting radiation in a wavelength range that is correlated to the wavelength range of the radiation the cell will receive. For example, PV cell 14 may be configured to convert radiation having wavelengths within a particular wavelength range into electricity, and optical component 24 may be configured to reflect radiation having wavelengths within at least a portion of that same wavelength range to cell 14, and to transmit the remainder of the radiation incident on surface 24. As described above, some or all of this transmitted radiation will be directed toward PV cells 16, 18 and 20 by internal reflection within waveguide 12. Accordingly, cell 16 may be configured to convert into electricity radiation having wavelengths within some or all of the range of wavelengths transmitted by surface 24 and transmitted directly through the side wall of the waveguide to cell 16. Similarly, dichroic prism 26 may be configured to transmit wavelengths to PV cell 18 that match the characteristics of cell 18, and to reflect remaining wavelengths toward distal cell 20 that match the characteristics of cell 20. In this manner, systems according to the present teachings may be designed to utilize a greater fraction of the incident solar energy than systems that utilize only a single type of PV cell.

It should be appreciated that converging lens 22 may be eliminated, and that the remaining elements of system 10 function similarly whether or not an optical concentrating element is present in the system. However, lens 22 serves to increase the solar radiation per unit area that reaches the PV cells of the system, and thus may serve to increase the electrical energy production of the system per unit area of PV material. When an optical concentrating element such as lens 22 is present, the longitudinal axis of waveguide 12 may be oriented substantially parallel to the optical axis of the concentrating element as in FIG. 1.

Alternatively (see FIG. 2), the longitudinal axis of the waveguide may be oriented substantially perpendicular to the optical axis of the concentrating element, in which case a reflective or dichroic surface may be used to direct incident radiation along the axis of the waveguide as will be described below in more detail. In general, the axis of the waveguide may be oriented at any desired angle with respect to the incident radiation, in which case the radiation may be directed along the waveguide with suitably oriented reflective or dichroic surfaces, or simply by choosing a shape of the waveguide that will result in appropriate internal reflections.

As depicted in FIG. 2, system 50 according to the present teachings functions in much the same way as system 10 depicted in FIG. 1. System 50 includes a waveguide 52 configured to receive and direct incident solar radiation, and a plurality of PV cells 54, 56, 58, 60 and 62 configured to receive radiation directed by the waveguide. An optical concentrating element, for example a converging lens 64, may be configured to concentrate and direct solar radiation onto waveguide 52 in much the same way that concentrating element 22 may be used to concentrate and direct radiation onto waveguide 12. As depicted in FIGS. 1 and 2, waveguide 52 is similar in many respects to waveguide 12, except that waveguide 52 has its longitudinal axis 65 oriented substantially perpendicular to the incident radiation and therefore also to the optical axis of converging lens 64.

Once incident radiation arrives at a receiving portion of waveguide 52, at least a portion of the radiation will be redirected along the length of the waveguide by a reflective element 66. Reflective element 66 may be a mirror or any similar highly reflective surface, in which case substantially all of the incident radiation will be redirected in the general direction of the longitudinal axis of the waveguide, or the reflective element may be a dichroic surface configured to transmit some of the incident radiation to PV cell 54 and to reflect the remainder of the incident radiation toward the remaining PV cells. If element 66 is a mirror, PV cell 54 will generally be omitted from the system since it will not receive any significant radiation. If element 66 is a dichroic element, it may be configured to transmit radiation within a wavelength range that is correlated to the sensitivity of cell 54 as has been described previously. In any case, the portion of the radiation directed down the length of waveguide 52 and generally along its longitudinal axis may be directed toward the various additional PV cells 56, 58, 60 and 62 by one or more of the same mechanisms used to direct radiation toward the cells of system 10.

Specifically, a reflective or at least partially reflective element such as a dichroic optical component 68 may direct radiation within a particular wavelength range toward PV cell 56, while allowing the remainder of the radiation arriving at component 68 to pass or be transmitted through the component. In addition, some of the radiation may pass through a side boundary 53 of waveguide 52 and to PV cell 58 by direct transmission. As described previously, this type of direct transmission may be arranged through the position of the waveguide relative to the incident radiation and/or by a suitable configuration of the shape of the waveguide in the vicinity of cell 58. Some radiation may pass through a dichroic or prismatic element 70 and then to PV cell 60. Element 70 and cell 60 may be chosen to have complementary properties, so that radiation passed by element 70 is efficiently utilized by cell 60. Finally, some radiation may pass through an end portion 72 of waveguide 52 and to PV cell 62, which may have properties chosen to match the wavelength range of the radiation that reaches it.

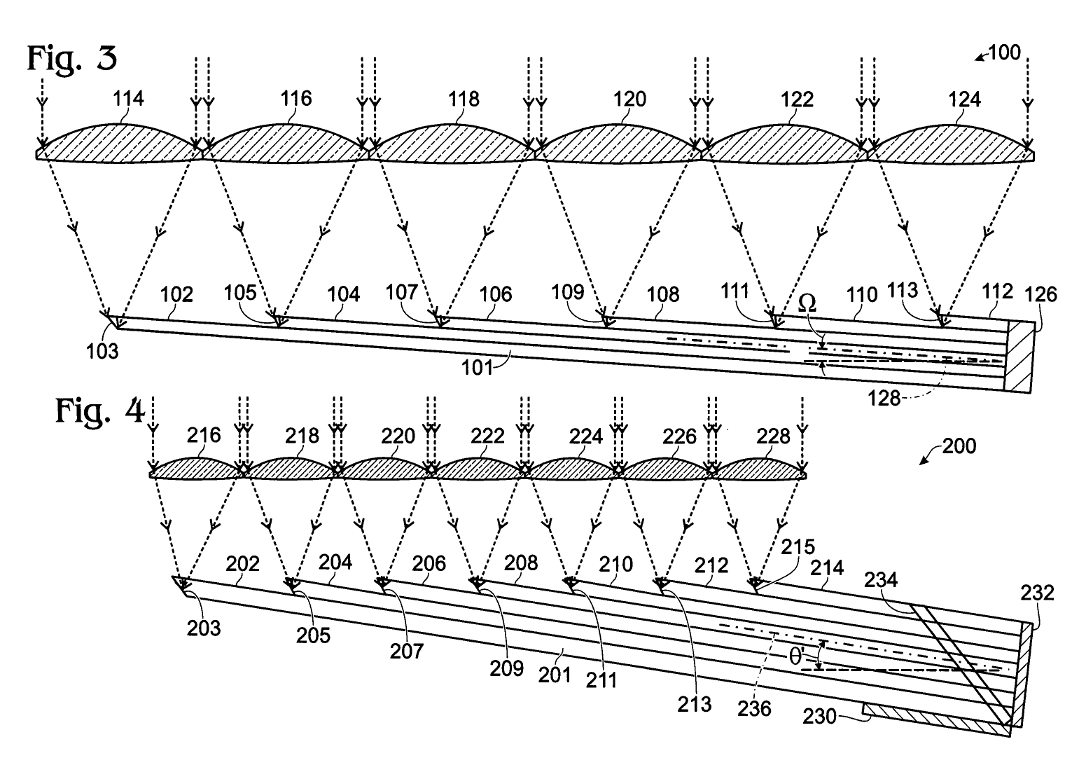

FIGS. 3-7 depict embodiments according the present teachings, in which a plurality of optical waveguides are placed in proximity to each other and configured to receive and jointly direct incident solar radiation toward one or more PV cells, by effectively acting together as a single waveguide. FIG. 3 shows a solar energy collection system or array, generally indicated at 100, including a plurality of waveguides 102, 104, 106, 108, 110, 112 that are tiled or stacked adjacent to each other. A plurality of optical concentrating elements 114, 116, 118, 120, 122, 124 are disposed above the waveguides, with a radiation receiving portion of each waveguide configured to receive and direct concentrated solar radiation from an associated one of the optical concentrating elements. A PV cell 126 is disposed at or near a distal end portion of the waveguides and configured to receive solar energy directed toward it by the waveguides. Cell 126 may be disposed in any location at which it will receive a desired portion of the radiation directed toward it by the collection of stacked waveguides, including at a position separated from the distal end of the waveguide stack.

In all of FIGS. 3-7, the optical concentrating elements take the form of converging lenses, and each waveguide is configured to receive solar energy focused by one of the converging lenses. However, it should be appreciated that other types of optical concentrators may be used, such as prisms, mirrors, Fresnel lenses, or the like, and that two or more optical concentrators may be used in conjunction with each waveguide. Furthermore, in some embodiments optical concentrating elements need not be present at all, in which case the waveguides may receive unconcentrated solar radiation directly from the sun. However, as described previously, the use of optical concentrating elements may increase the amount of solar radiation that is received and converted to electricity per unit area of PV cell material.

Each waveguide in FIGS. 3-7 may be substantially similar to waveguide 52 depicted in FIG. 2, with a reflective surface such as a mirror disposed at or in proximity to a receiving end of each waveguide to direct incident radiation generally along the longitudinal axis of each waveguide. For example, waveguide 102 may include a receiving end 103 equipped with a mirror or other reflective surface configured to direct incident radiation along the longitudinal axis of the waveguide, waveguide 104 may include a receiving end 105 configured for a similar purpose, and the remaining waveguides may include receiving ends 107, 109, 111 and 113 all configured to direct radiation generally along the length of each waveguide. In some embodiments, the receiving end of each waveguide may be configured such that incident radiation will be internally reflected along the length of the waveguide, in which case dedicated reflective surfaces such as mirrors may not be necessary at the receiving ends of the waveguides. This internal reflection may be accomplished through a suitable choice of shape, orientation, and index of refraction of the waveguides as has previously been described. Collectively, the stacked waveguides may be effectively viewed as a single waveguide defining a single longitudinal axis, such as axis 128 in FIG. 3, along which radiation will be directed.

Waveguides 102, 104, 106, 108, 110, 112 in FIG. 3 vary in length so that each waveguide extends laterally from a position under the corresponding optical concentrating element to a distal end portion disposed nearest to PV cell 126. Thus, waveguide 102 is the longest, and waveguides 104, 106, and so forth are progressively shorter as each waveguide's receiving end is disposed closer to cell 126. To maintain the receiving ends of all of the waveguides at a common distance from the corresponding converging lens (i.e., with the receiving ends of the waveguides in a horizontal plane as depicted in FIGS. 3-5), the longitudinal axis of each waveguide may be oriented at a slight angle Ω, θ′, θ″ relative to a plane defined by the converging lenses. The angle may, for example, be between five and ten degrees, and is approximately five degrees in the embodiment of FIG. 3, and approximately eight degrees in the embodiment of FIG. 4. However, it should be appreciated that the angular orientation of the waveguides relative to the plane of the optical concentrating elements is primarily a function of the thickness of the waveguides and their linear density in the system, which can be chosen to have a wide variety of values.

Waveguides 102, 104, 106, 108, 110, 112 are disposed adjacent to each other along their lateral side boundaries in FIG. 3. In other words, the top surface of waveguide 102 is adjacent to the bottom surface of waveguide 104 in the region where those two surfaces overlap, the top surface of waveguide 104 is adjacent to the bottom surface of waveguide 106 in the region where those two surfaces overlap, and so forth. If the waveguides are constructed from the same material (at least in the vicinity of their lateral boundaries) and are adjacent to each other in this manner, there are no internal boundaries in the collection of stacked waveguides where radiation would encounter a variation in index of refraction and undergo an internal reflection. Thus, the plurality of waveguides depicted in FIG. 3 may essentially function as a single waveguide or waveguide stack 101, with internal reflections only at the outer boundaries of the collection of waveguides. Even if the waveguides have slight variations in their indices of refraction, proper construction and alignment of the adjacent waveguides may result in minimal or negligible reflections at the internal boundaries.

Alternatively, waveguides at the center of stack 101 (i.e., those corresponding to optical concentrating elements at the center of FIG. 3 as viewed from left to right) may be configured to have relatively higher indices of refraction, with some or all of the remaining waveguides toward the top and bottom of the stack having progressively lower indices of refraction. This configuration can be accomplished through a suitable choice of materials having desired optical properties, and may result in some amount of internal reflection at the boundaries between waveguides toward the top and bottom of the stack, so that the radiation collected towards the center of the stack is kept more toward the center of the stack and has a somewhat lesser probability of being lost through an external lateral boundary before it reaches PV cell 126. Radiation that does not begin towards the center of the stack with in general be concentrated less towards the center of the stack.

FIG. 4 shows another solar energy collection system, generally indicated at 200, including a waveguide stack 201 formed from a plurality of waveguides 202, 204, 206, 208, 210, 212, 214 that are layered or tiled adjacent to each other. Optical concentrating elements 216, 218, 220, 222, 224, 226, 228 are disposed above the waveguides, and each waveguide is configured to receive and direct solar energy from an associated optical concentrating element in the manner of system 100. For example, waveguide 202 may include a receiving end portion 203 including a mirror or other reflective surface configured to direct solar energy from optical concentrating element 216 generally along the length of waveguide 202. Similarly, waveguides 204, 206, 208, 210, 212 and 214 may respectively include receiving end portions 205, 207, 209, 211, 213, and 215 configured for a similar purpose. The combined effect of the reflections that occur at the receiving ends of the individual waveguides is to direct incident radiation generally along a common longitudinal axis 236 of waveguide stack 201.

As in FIG. 3, the waveguides in FIG. 4 are angled slightly away from the optical concentrating elements, so that the receiving end of each waveguide may be disposed at approximately the same distance from its associated optical concentrating element. System 200 is thus similar in many respects to system 100, except that two PV cells 230, 232 are disposed in proximity to the distal end of the collection of stacked waveguides. A dichroic optical element 234 is positioned to transmit one portion of the solar radiation it receives toward PV cell 232, and to reflect or otherwise direct a second portion of the solar radiation it receives toward PV cell 230.

As has been described previously with respect to the embodiments of FIGS. 1-2, the properties of dichroic element 234 and PV cells 230, 232 may be correlated with each other to increase the efficiency of the system. More specifically, element 234 may be configured to transmit radiation within a wavelength range that cell 232 is configured, at least in part, to absorb and convert to electricity. Similarly, element 234 may be configured to redirect radiation within a wavelength range that cell 230 is configured, at least in part, to absorb and convert to electricity. In this manner, system 200 may make more efficient use of incident radiation than systems employing just a single type of PV cell.

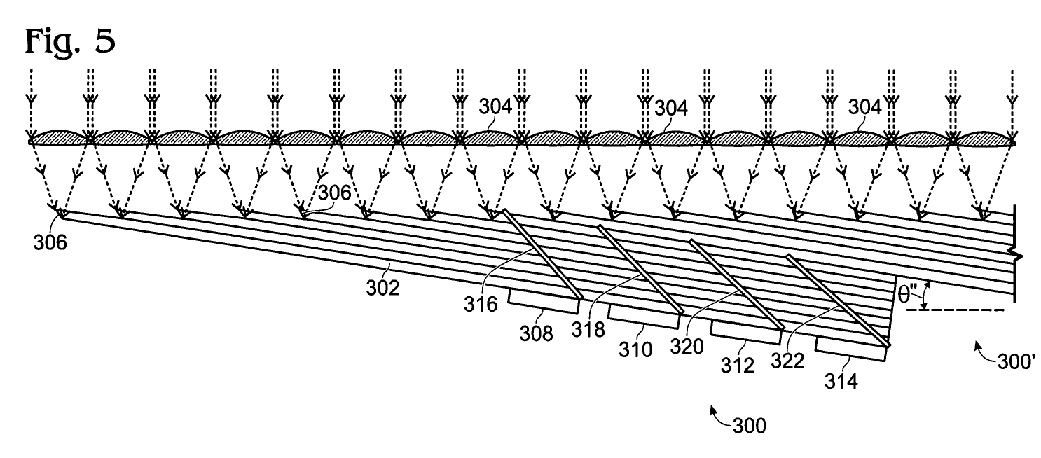

FIG. 5 depicts another solar energy collection system, generally indicated at 300, according to aspects of the present teachings. The embodiment of FIG. 5 is generally similar to the embodiment of FIG. 4, including a plurality of waveguides disposed in physical contact to act effectively as a single waveguide or waveguide stack 302, and a plurality of substantially similar optical concentrating elements 304 disposed above the waveguides. As in the embodiments of FIG. 3 and FIG. 4, the waveguides in FIG. 5 are angled, with a receiving end 306 of each waveguide disposed at approximately the same distance from an associated optical concentrating element. Each waveguide is configured to receive and direct solar energy from the associated optical concentrating element generally along the longitudinal axis of stack 302 and toward several PV cells 308, 310, 312 and 314. In this embodiment, each of the four depicted PV cells is configured to absorb and convert to electricity solar radiation within a particular wavelength range, and a plurality of dichroic surfaces 316, 318, 320 and 322 are disposed within the stack of waveguides and configured to reflect a portion of the solar spectrum correlated to the properties of the associated PV cell.

For example, PV cell 308 may be sensitive to high-energy solar radiation (such as UV radiation), in which case dichroic surface 316 may be configured to reflect high-energy radiation toward cell 308 and to transmit all lower-energy solar radiation. PV cell 310 may be sensitive to mid-energy solar radiation, such as near UV and short wavelength visible light, in which case dichroic surface 318 may be configured to reflect mid-energy radiation toward cell 310 and to transmit lower-energy radiation. PV cell 312 may be sensitive to the remainder of the visible spectrum, and dichroic surface 320 may be configured to reflect those wavelengths toward cell 312 and to transmit longer wavelength radiation. PV cell 314 may be sensitive to longer wavelength radiation such as infrared radiation, and dichroic surface 322 may be configured to reflect that portion of the spectrum toward cell 314. Alternatively, a mirror may be used in place of dichroic surface 322 to reflect all remaining radiation toward cell 314. If a dichroic surface 322 is used, one or more additional PV cells (not shown in FIG. 5) may be disposed at other positions in proximity to the stacked waveguides, such as at or near the distal end portion of the stack, and configured to absorb and convert to electricity other wavelength ranges and/or stray solar radiation that for some reason is not otherwise absorbed by cells 308, 310, 312 or 314.

FIG. 5 also shows portions of a second solar collection system 300′ disposed to the right of array 300. This illustrates that the solar collection arrays described by the present teachings may be repeated at regular intervals (or otherwise), in any manner suitable for collecting a desired amount of solar radiation. Using such repeating arrays may simplify the construction of waveguides by limiting the need to construct extremely long waveguides, and also may minimize transmission losses that might occur over greater waveguide lengths. Furthermore, it should be appreciated that the wavelength ranges described above with respect to the embodiment of FIG. 5 are merely exemplary, and that the present teachings contemplate that any number of PV cells, sensitive to any wavelength ranges, may be positioned to receive solar radiation directed by stacked waveguides 302, 304, etc. and associated dichroic surfaces.

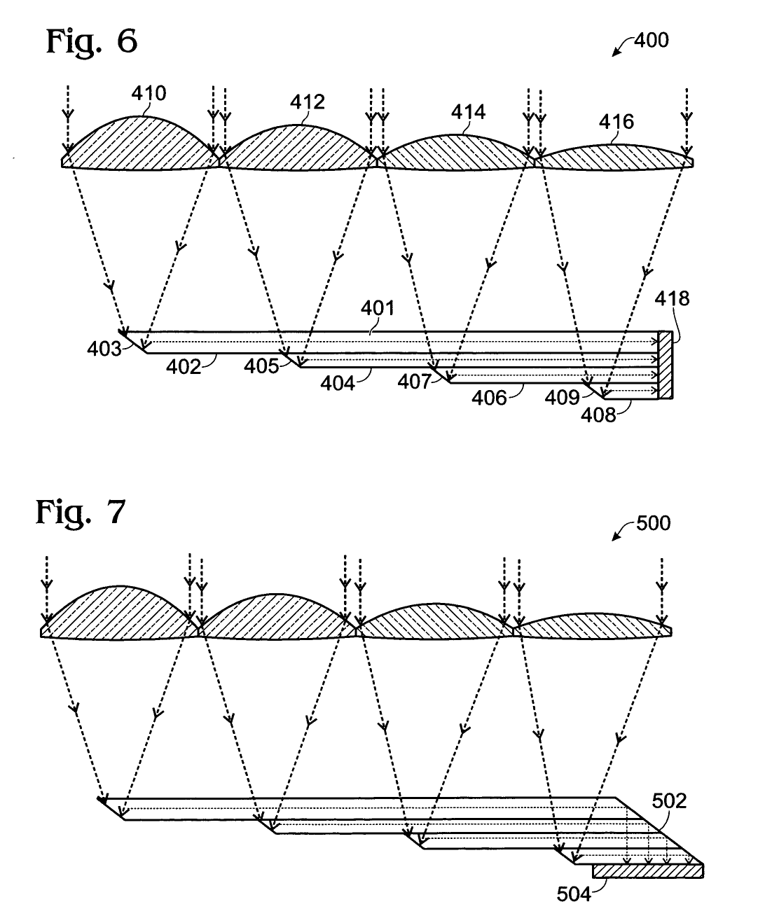

FIG. 6 shows a solar energy collection system 400 that has another arrangement of stacked waveguides 402, 404, 406 and 408. Optical concentrating elements 410, 412, 414 and 416 are configured to concentrate and direct solar radiation onto the respective waveguides, and a PV cell 418 is disposed at the distal end of the waveguides and configured to receive radiation jointly directed toward it by the waveguides. It should be appreciated that the present teachings contemplate adding one or more additional PV cells to the embodiment of FIG. 6, along with dichroic surfaces configured to direct suitable radiation toward each cell in the same manner described above, for example with respect to the embodiment depicted in FIG. 5.

Unlike in FIGS. 3-5, the waveguides of FIG. 6 are not oriented at an angle relative to the plane defined by the optical concentrating elements, but rather are stacked or tiled substantially parallel to that plane. As a result, the receiving end of each waveguide is not disposed at the same distance from its respective optical concentrating element. Instead, receiving ends 403, 405, 407 and 409 of the waveguides are located progressively further away from their associated optical concentrating elements, with receiving end 409 of waveguide 408 disposed furthest away. Accordingly, the optical concentrating elements 410, 412, 414 and 416 are not identical to each other, but instead have various focal lengths, with the focal length of each concentrating element chosen so that radiation is focused at or near the receiving end of the associated waveguide. As FIG. 6 indicates, appropriate focal lengths may be attained, for example, by progressively decreasing the radius of curvature of each successive lens 412, 414, and 416, resulting in progressively longer focal lengths.

FIG. 7 shows yet another alternate embodiment of a solar collection system, generally indicated at 500. The embodiment of FIG. 7 is substantially similar to the embodiment of FIG. 6 in many respects, and therefore only the differences between system 500 and system 400 of FIG. 6 will now be described. In collection system 500, each waveguide has a slanted distal portion, so that the waveguides collectively form an angled distal surface 502. Surface 502 may be configured to internally reflect substantially all, or at least a significant portion of the solar radiation directed toward the distal end of the stack of tiled waveguides. Accordingly, a PV cell 504 may be disposed in a position to receive the radiation reflected by the surface. This may allow for more convenient collection of radiation and/or integration of multiple arrays into a working PV module. Alternatively, if surface 502 does not provide sufficient internal reflection toward cell 504 merely by virtual of its angle and the index of refraction of the waveguide, a reflective surface (not shown) may be disposed at or near the vicinity of surface 502 to reflect radiation toward the PV cell.

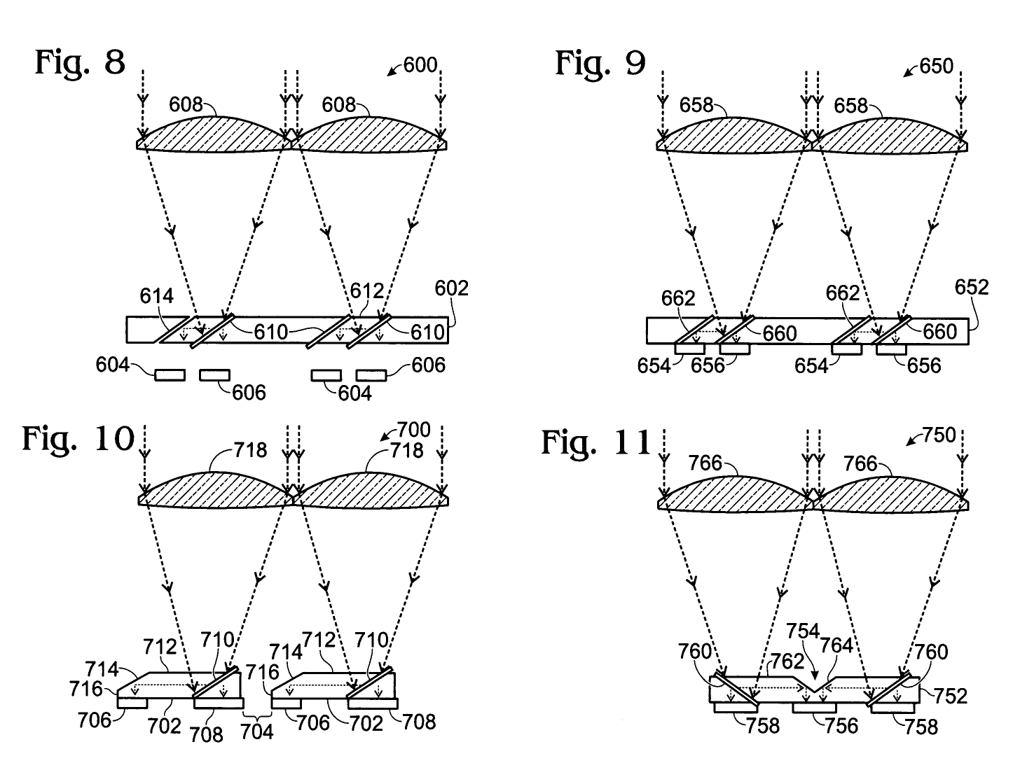

FIGS. 8-11 show various other aspects of the present teachings. These drawings each show embodiments of what will be described herein as the “sheet approach,” in which a continuous sheet of waveguide material is used to construct a solar energy collection system. FIG. 8 shows a first embodiment of a solar energy collection system according to the sheet approach, generally indicated at 600. System 600 includes a sheet of waveguide material 602, and PV cells 604, 606 of two different types configured to absorb solar radiation directed by the waveguide material. A pair of substantially similar optical concentrating elements 608 is disposed above the waveguide material, to concentrate solar radiation and direct it toward the waveguide sheet.

When solar radiation penetrates the waveguide sheet, the radiation from each concentrating element will encounter a dichroic surface 610, which is configured to transmit radiation within a first range of wavelengths and to reflect radiation within a second range of wavelengths. Surfaces 610 may be disposed within gaps or grooves of sheet 602, or they may be otherwise embedded in the sheet in any suitable manner. The radiation transmitted through the dichroic surfaces will be directed toward one of PV cells 606, which are configured to convert radiation within at least a portion of the first (transmitted) range of wavelengths to electricity. The geometry of system 600 may be configured so that substantially all of the radiation incident on dichroic surfaces 610 will either be transmitted toward the associated cell 606 or reflected.

Depending on the angle of reflection, the radiation reflected by dichroic surfaces 610 may encounter a top surface 612 of the waveguide sheet (not shown), another dichroic surface 610 (as in the right-hand portion of FIG. 8), or a diagonal surface 614 that has been formed in conjunction with a gap, i.e., a layer of air or vacuum, in sheet 602 (as in the left-hand portion of FIG. 8). Surface 614 may be formed, for example, by etching or scribing away a portion of sheet 602. In either case, some or all of the radiation reflected from surfaces 610 may be internally reflected from surfaces 612 and/or 614 according to principles of optics that have already been described in detail. The geometry of system 600 may be configured so that substantially all of the radiation reflected from either of surfaces 612 or 614 will be directed toward an associated one of PV cells 604, each of which is configured to convert radiation within at least a portion of the second (reflected) range of wavelengths to electricity. In this manner, substantially all of the solar radiation received by waveguide sheet 602 may be directed toward one of PV cells 604, 606, and each cell may receive radiation correlated with its wavelength range of peak sensitivity.

FIG. 9 shows a second solar energy collection system according to the sheet approach, generally indicated at 650. System 650 is similar to system 600 in some respects. However, in system 650, a sheet of waveguide material 652 is disposed in closer proximity to PV cells 654, 656, with the cells substantially adjacent to the waveguide sheet. Optical concentrating elements 658 concentrate and direct solar radiation to sheet 652, but in addition to dichroic surfaces 660, the system also includes mirrors or similar reflective surfaces 662 to direct reflected radiation toward cells 654. Reflective surfaces 662 may be used in place of the dichroic surface 610 positioned above right-hand cell 604 and gap 614 positioned above left-hand cell 604 in system 600, to insure total or near-total reflection of incident radiation toward cells 654. Surfaces 660 and 662 may be disposed within gaps or grooves of sheet 652, or they may be otherwise embedded in or applied to the sheet in any suitable manner. Aside from the locations of the PV cells in closer proximity to the waveguide sheet and the presence of reflective surfaces 662, system 650 is substantially similar to system 600 and accordingly will not be described in further detail.

FIG. 10 shows a third solar energy collection system according to the sheet approach, generally indicated at 700. System 700 includes a sheet of waveguide material 702, within which a central gap 704 has been formed to create two distinct regions of the sheet material and to induce internal reflections as described in more detail below. Gap 704 may be formed within the sheet by etching, scribing, ablation, or any other suitable method. Two types of PV cells 706, 708 are disposed in proximity to the lower boundary of each distinct region of sheet 702, and configured to receive most or substantially all of the solar radiation incident on the waveguide sheet.

Specifically, a dichroic element 710 is disposed above each of cells 708 and configured to transmit radiation within an appropriate wavelength range to cells 708. Dichroic elements 710 reflect the remainder of the incident radiation toward cells 706, and the reflected radiation is further redirected toward cells 706 by internal reflection from one or more of the top surface 712, a diagonal edge portion 714, or a vertical edge portion 716 of sheet 702. In this manner, most or substantially all of the radiation reflected by the dichroic elements 710 eventually reaches cells 706, which may be configured to convert energy within the range of reflected wavelengths to electricity. It should be appreciated that mirrors may be disposed at or near diagonal edge portions 714 and/or vertical edge portions 716, to further facilitate reflection of radiation toward cells 706. Optical concentrating elements 718, which commonly take the form of converging lenses, may be disposed above the waveguide sheet and configured to focus concentrated solar radiation onto the sheet.

FIG. 11 shows a fourth solar energy collection system, generally indicated at 750, according to the sheet approach. System 750 is similar in some respects to system 700 of FIG. 10, but includes only a central groove in the waveguide sheet rather than a complete gap. More specifically, system 750 includes a sheet of waveguide material 752, within which a central groove 754 has been formed to induce internal reflections. A central PV cell 756 is disposed under the central groove, and PV cells 758 are disposed at either side of the central cell. Dichroic elements 760 are disposed above each of cells 758 and configured to transmit and reflect radiation toward cells 758 and 756, respectively, in a manner that has previously been described. The radiation reflected by dichroic elements 760 may be further redirected toward cell 756 by internal reflection from the top surface 762 of sheet 752 and/or diagonal edge portions 764 that form the sides of groove 754. As before, optical concentrating elements 766 may focus radiation onto the waveguide sheet, and the dichroic surfaces may have properties correlated with the sensitivities of the PV cells.

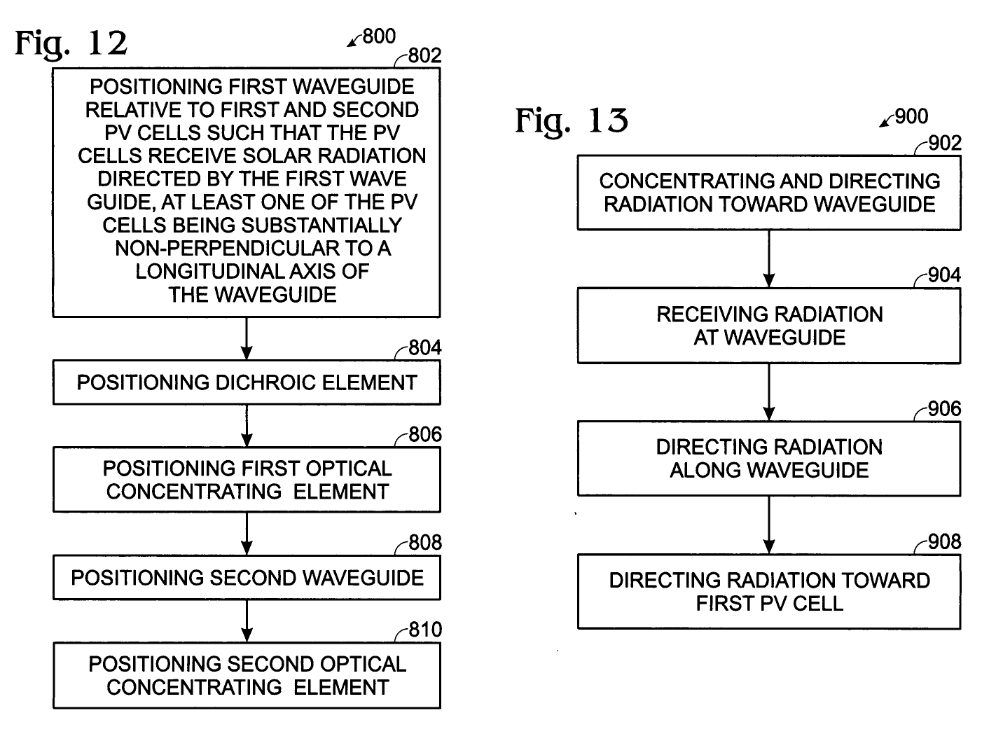

FIG. 12 depicts a method of manufacturing a solar energy collection system, generally indicated at 800, according to aspects of the present teaching. At step 802, a waveguide is positioned relative to first and second photovoltaic cells such that the photovoltaic cells are configured to receive solar radiation directed by the waveguide. As has been described previously, at least one of the cells is positioned with its radiation receiving surface oriented substantially non-perpendicular to a longitudinal axis defined by the waveguide. The radiation receiving surface of the non-perpendicular cell may be oriented substantially parallel to the axis of the waveguide, in which case it may also be adjacent to a lateral side of the waveguide and/or in direct contact with the waveguide, or the cell may be oriented with its surface at some other non-perpendicular angle to the waveguide. Whether parallel or non-parallel to the axis of the waveguide, the non-perpendicular cell may be separated from the waveguide by a desired distance rather than adjacent to it.

At step 804 of method 800, a dichroic element may be positioned relative to the waveguide such that the dichroic element is configured to reflect one portion of radiation within the waveguide toward the non-perpendicular cell, and to transmit another portion of the radiation within the waveguide toward the other PV cell. This second cell may, for example, be disposed at an end portion of the waveguide, in which case its radiation receiving surface may be oriented substantially perpendicular to the axis of the waveguide, or the second cell may be disposed along a later side of the waveguide, in which case radiation transmitted through the dichroic element may be reflected toward the second cell be a reflective surface such as a mirror, another dichroic element, or by internal reflection from an interior surface of the waveguide.

At step 806 of the method of FIG. 12, an optical concentrating element is positioned to direct solar radiation toward a receiving end of the waveguide. As has been described, suitable optical concentrating elements include converging lenses, mirrors, Fresnel lenses, prisms, and the like. At step 808, a second waveguide may be positioned to direct radiation toward the PV cells in a manner similar to the first waveguide. The second waveguide may be oriented substantially parallel with the first waveguide and may be adjacent to the first waveguide, so that the two waveguides function as a single waveguide to direct radiation generally in the direction of a common longitudinal axis. At step 810, a second optical concentrating element may be positioned to concentrate and direct radiation toward a receiving end of the second waveguide, in a manner similar to the direction of radiation toward the first waveguide by the first optical concentrating element.

FIG. 13 depicts a method of collecting solar radiation, generally indicated at 900, according to aspects of the present teachings. At step 902, radiation is concentrated and directed toward a waveguide by one or more optical concentrating elements such as those described in detail above. It should be appreciated that the remainder of method 900 will function even without such concentration. At step 904, radiation is received at the waveguide. This radiation may be concentrated or unconcentrated, depending on whether step 902 is performed. At step 906, the received radiation is directed along a longitudinal axis of the waveguide. Depending on the orientation of the waveguide, this may occur naturally (i.e., without substantial redirection), or the received radiation may be redirected by a mirror or other reflective surface, including an internal surface of the waveguide, disposed at the receiving end of the waveguide.

At step 908 of method 900, at least a portion of the radiation directed along the axis of the waveguide is further directed toward a PV cell having a radiation receiving surface oriented substantially non-perpendicular to the axis of the waveguide. As described above, this orientation distinguishes the method from one in which all of the radiation within the waveguide is collected by a PV cell oriented substantially perpendicular to the axis of the waveguide, such as one disposed at a distal end of the waveguide. For example, the non-perpendicular PV cell may be disposed along a lateral side of the waveguide, and oriented substantially parallel or at a predetermined angle to the waveguide axis. In any case, the radiation may be directed toward the PV cell by a mirror, a dichroic surface, an internal surface of the waveguide that results in internal reflection, or by any other at least partially reflective surface. As has been previously described in detail, additional PV cells may be disposed along lateral sides of the waveguide and/or at an end portion of the waveguide to collect any radiation that is not directed toward the first non-perpendicular cell.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the inventions includes all novel and nonobvious combinations and subcombinations of the various elements, features, functions, and/or properties disclosed herein. The following claims particularly point out certain combinations and subcombinations regarded as novel and nonobvious. Inventions embodied in other combinations and subcombinations of features, functions, elements, and/or properties may be claimed in applications claiming priority from this or a related application. Such claims, whether directed to a different invention or to the same invention, and whether broader, narrower, equal, or different in scope to the original claims, also are regarded as included within the subject matter of the inventions of the present disclosure.

We claim:

1. A solar energy collection system comprising:
a first photovoltaic cell sensitive to radiation in a first wavelength range;
a second photovoltaic cell sensitive to radiation in a second wavelength range; and
a first waveguide configured to direct radiation toward the first and second photovoltaic cells and defining a longitudinal axis substantially non-perpendicular to a radiation receiving surface of at least one of the photovoltaic cells.

2. The solar energy collection system of claim 1, further comprising a first optical concentrating element configured to concentrate and direct radiation toward the first waveguide.

3. The solar energy collection system of claim 1, further comprising a dichroic optical element configured to direct a first potion of radiation toward the first photovoltaic cell and a second portion of radiation toward the second photovoltaic cell.

4. The solar energy collection system of claim 3, wherein the dichroic optical element is configured to reflect radiation within the first wavelength range toward the first photovoltaic cell and to transmit radiation within the second wavelength range toward the second photovoltaic cell.

5. The solar energy collection system of claim 1, wherein the longitudinal axis of the first waveguide is substantially parallel to the radiation receiving surface of the at least one photovoltaic cell.

6. The solar energy collection system of claim 5, wherein the at least one photovoltaic cell is in direct physical contact with the first waveguide.

7. The solar energy collection system of claim 1, further comprising a reflective surface configured to reflect radiation generally along the longitudinal axis of the first waveguide.

8. The solar energy collection system of claim 1, further comprising at least a second waveguide defining a longitudinal axis substantially non-perpendicular to the radiation receiving surface of at the least one photovoltaic cell and configured to direct radiation toward the first and second photovoltaic cells.

9. The solar energy collection system of claim 8, further comprising a first converging lens configured to concentrate and direct solar radiation toward the first waveguide, and a second converging lens configured to concentrate and direct solar radiation toward the second waveguide.

10. The solar energy collection system of claim 9, wherein the converging lenses have substantially similar focal lengths and wherein a receiving end of each waveguide is disposed at approximately the same distance from a corresponding one of the converging lenses.

11. The solar energy collection array of claim 10, wherein the longitudinal axis of each waveguide is oriented at an angle of between five and ten degrees relative to a plane defined by the converging lenses.

12. The solar energy collection array of claim 9, wherein a receiving end of the first waveguide is disposed at a first distance from the first lens corresponding to a focal length of the first lens, and a receiving end of the second waveguide is disposed at a second distance from the second lens corresponding to a focal length of the second lens.

13. A method of manufacturing a solar energy collection system, comprising positioning a first waveguide relative to first and second photovoltaic cells such that the photovoltaic cells are configured to receive solar radiation directed by the first waveguide and such that a radiation receiving surface of at least one of the cells is oriented substantially non-perpendicular to a longitudinal axis defined by the first waveguide.

14. The method of claim 13, further comprising positioning a dichroic optical element relative to the first waveguide such that the dichroic element is configured to reflect a first portion of radiation directed by the first waveguide toward the first cell and to transmit a second portion of radiation directed by the first waveguide toward the second cell.

15. The method of claim 13, wherein positioning the waveguide relative to the cells includes orienting the radiation receiving surface of the at least one cell substantially parallel to the longitudinal axis defined by the waveguide.

16. The method of claim 13, further comprising:
positioning a second waveguide substantially parallel to the first waveguide and such that the photovoltaic cells are configured to receive solar radiation directed by the second waveguide;
positioning a first optical concentrating element to direct solar radiation toward a receiving end of the first waveguide; and
positioning a second optical concentrating element to direct solar radiation toward a receiving end of the second waveguide.

17. The method of claim 16, wherein positioning the first and second waveguides includes positioning the receiving ends of the waveguides substantially equidistant from the corresponding optical concentrating elements.

18. A method of collecting radiation comprising:
receiving radiation at a receiving end a waveguide;
directing the radiation along a longitudinal axis of the waveguide; and
directing at least a portion of the radiation toward a first photovoltaic cell having a radiation receiving surface oriented substantially non-perpendicular to the longitudinal axis of the waveguide.

19. The method of claim 18, wherein the radiation receiving surface of the first cell is oriented substantially parallel to the longitudinal axis of the waveguide, and wherein directing at least a portion of the radiation toward the first cell includes reflecting a first portion of the radiation toward the first cell and transmitting a second portion of the radiation toward a second photovoltaic cell.

20. The method of claim 17, further comprising concentrating and directing the radiation toward the waveguide with an optical concentrating element.
